(19) United States
(12) Patent Application Publication
(10) Pub. No.: US 2004/0260760 A1
(43) Pub. Date: Dec. 23, 2004

(54) Virtual wireless network

(76) Inventor: Jonathan Curnyn, Bucks (GB)

Correspondence Address: BEYER WEAVER & THOMAS LLP, P.O. BOX 778, BERKELEY, CA, 94704-0778, US

(21) Appl. No.: 10/490,881

(22) PCT Filed: Mar. 25, 2002
(86) PCT No.: PCT/GB02/04349

(30) Foreign Application Priority Data
Sep. 25, 2001 (GB) 0123057.2

(51) Int. Cl. H03M 13/03

(52) U.S. Cl. 709/201

(57) ABSTRACT

The present invention provides a virtual wireless network (VWN) system capable of integrating disparate wireless networks. The system includes a plurality of data stores containing information about Users, devices, services, policies and network configuration. This information is used by a VWN Processing Engine to establish and operate the network and to optimise the services provided across the VWN.

### FIELD OF THE INVENTION

The present invention relates to wireless networks and the provision of services across a range of network access technologies.

### BACKGROUND TO THE INVENTION

Multiple wireless technologies exist today, each with their own applications and uses, and as such a company or organisation wishing take full advantage of the benefits of wireless networks will need to implement systems from multiple vendors. These different systems are basic network access solutions which offer few if any services across the network, let alone any commonality which allows the same services to be offered across the range of networks.

The uses of a wireless network can be numerous, and each organisation will have their specific needs and requirements from the network, and a set of applications to run across the network. The present invention addresses these problems to offer a single network solution.

### SUMMARY OF THE INVENTION

According to a first aspect of the present invention, a virtual wireless network (VWN) system comprises:

a number of networks;

a user data store including information relating to network Users;

a device data store including information relating to network devices;

a services data store including information relating to types of service available at network locations;

a policy data store including information relating to network policy to be implemented on the VWN;

a VWN configuration data store including information on the operation of the VWN;

a plurality of network modules; and,

a VWN Processing Engine connected to each data store and to each network module, and having an input for receiving network events, a set of routines for processing each event, and an output for commanding network modules. In use, the VWN Processing Engine controlling the operation of one or more network modules in accordance with a network event and in dependence on information in each of the data stores.

According to a second aspect of the present invention, a computer program product comprises computer executable code for establishing and operating a virtual wireless network according to the first aspect of the present invention.

According to a third aspect of the present invention, a method of establishing a virtual wireless network (VWN) across one or more networks, comprises the steps of:

providing a user data store including information relating to network Users;

providing a device data store including information relating to network devices;

providing a services data store including information relating to types of service available at network locations;

providing a policy data store including information relating to network policy to be implemented on the VWN;

providing a VWN configuration data store including information on the operation of the VWN;

providing a plurality of network modules; and,

providing a VWN Processing Engine connected to each data store and to each network module, and having an input for receiving network events, a set of routines for processing each event, and an output for commanding network modules. In use, the VWN Processing Engine controlling the operation of one or more network modules in accordance with a network event and in dependence on information in each of the data stores.

The invention manages a number of different data stores or databases, which may be at one location or distributed over a number of different locations and even over different networks.

The user database includes information per User such as his/her devices, for example Dell laptop, Compaq PDA, Nokia GPRS Smart phone, user priority (low/medium/high), tariff allowed (low/medium/high), security required etc.

The device database includes information on per device and entries may include the device's security capability, applications installed, messaging support, and wireless interface, for example Bluetooth or GPRS.

The services database details the type of service available at a specific location, for example the 1st floor of corporate office or public hotspot. The entries per location may include security needed (e.g. if data is to be passed over a public network), service available (e.g. telephony), data format definition (e.g. low resolution graphics only) etc.

The policy database is a repository of the policies an administrator wants implemented on the VWN through a set of rules and entered parameters, which define the precedence of the various databases.

The VWN configuration database is an internal store of how the VWN will operate and instructs the VWN Processing Engine which network modules use when processing a network event. This database is different from the others in that it doesn't contain information of the depoloyer, but information which is solely for the VWN and is produced by the VWN software during installation and subsequent operation.

The invention provides a framework which allows a number of network modules to be combined to provide improved and optimal services over, and operation of, the VWN. These modules usually each perform a separate function such as messaging, security, mobility, diagnostics etc., and can loosely be grouped into 3 categories of Services Modules, Features Modules and Control Modules. The Services Modules are combined by the invention to offer services over the VWN, regardless of whether the invention actually participates in the operation of the underlying physical networks. The Features and Control Modules are used when the invention actually operates part or all of one or more of the physical networks comprising the VWN. For example, the VWN may be comprised of a public cellular network, one or more corporate wireless LANs and a Bluetooth Service in a Public hotspot. In this instance, the invention provides services across all 4 of the physical networks, but may provide Features and Control for only the corporate wireless LANs. For the wireless LANs the invention combines the Features and Control modules to operate an enhanced wireless network where mobility services are now linked to security services to ensure security levels are maintained during hand-off operations.

The network modules each perform a set of dedicated functions but are combined to greater effect in the framework by the VWN Processing Engine, where the network modules and the Processing Engine communicate through a set of defined messages. These messages can be fall into three categories, the first being Event Messages which are used to queue events to the VWN Processing Engine, the second being Database Messages which are used to request information from the database and interpret results, and the third being Command Messages which are used by the VWN Processing Engine to instruct modules to perform a function. The network modules can therefore be said to generate events and respond to commands, in addition to their basic functionality, in order to operate within the framework.

The framework provided by the invention, permits enhanced service provision and operation of the VWN as opposed to using enhanced or expanded standalone network modules. For example, the invention has a Content Tailoring Module, but this module may or may not contain unique Content Tailoring functionality, but the invention ensures that the Content Tailoring is applied to optimise services provided to the user in an easy to use way, in accordance with the policies set for the VWN. The framework incorporates the data stores, the VWN Processing Engine, the Distribution System and the network modules, where the network modules are supplied as bespoke components designed for the invention using a number of defined interfaces internal to the invention. Additionally, third party network modules and functions can be added to the VWN hence providing an extensible architecture, where the third party network modules are individually interfaced to the invention. For example, an industry leading Positioning Module can be added to the invention by means of an interface module which is provided with the third party network module to allow the invention to use his new function to enhance the existing Location Service provided.

Preferably, the system further comprises a Distribution System connected to the VWN Processing Engine, the combination being operative to deliver services to Users across the VWN.

The VWN Processing Engine and Distribution System work together to deliver a service to a User's device at his/her location in an optimum manner. The VWN Processing Engine does the thinking or control plane piece of this, and the Distribution System sends and receives from the physical interfaces such as an SMS gateway. Once the destination is selected and any conversion performed, the invention causes any information to be routed, but the actual delivery is done by standard networking equipment (e.g. corporate routers, mobile operator GPRS switching centres etc.). When the invention operates and enhances parts of a physical network within the VWN the Distribution System takes similar networks and provides uniform features and control across them, for example a single Mobility Manager for both WLAN and Bluetooth.

Network events are events that are typically generated by Users, by elements within the invention or which interface to the invention, or by elements within the physical networks. In each case the network event and accompanying information is queued to the VWN processing Engine to be processed. A number of such network events are introduced below. User generated network events include when a User has logged on to his corporate network, or User A has sent a message to User B via the invention messaging service. Events generated by the invention, which may come from any element in the invention such as a network module or the VWN Processing Engine, include an alert from the Capacity Manager indicating a part of the VWN is now operating beyond a set threshold, a message from the Mobility Manager indicating a hand-off operation has failed, a message from the Diagnostics Manager indicating that an Access Point failure has been detected, or a message from an external billing server indicating a user's subscription has expired. Elements within the physical networks may also generate events such as an Access point indicating that a User has lost contact, or a message from an SMS gateway indicating the SMS network is down.

The VWN Processing Engine operates on events queued to it, these events being sourced as mentioned above. These events are queued with information relevant to each event in accordance with defined Event Message fields, including general information such as username, network address etc., and information specific to the source of the event. If the event is from the Mobility Manager it will have specific mobility information required to process the event. The VWN will access the databases with the provided information, and be returned information such as introduced earlier (e.g. security policy, cost policy) in accordance with defined Database Message fields. The VWN Processing Engine will then effect the actions required for the event, which can occur in one of two methods, both in accordance with a set of defined Command Messages. The first method is whereby the VWN Processing Engine will communicate with the modules using the Command Messages, and the second method is whereby the VWN processing may instruct the modules to communicate directly to conclude processing of the specific event. This second method uses the same Command Messages.

For each event that is queued to the VWN Processing Engine, the VWN Processing Engine has a corresponding set of routines or tasks that it needs to perform to accomplish the functions that may be requested in an event. For example, when the VWN Processing Engine performs a Mobility event, it reads the database stores which in turn indicate which network modules are in operation, such as Security, Capacity Management, and involves these network modules in the processing of the event. When a new module is added to the invention, or a network module is upgraded with new functionality, the VWN Processing Engine routines are automatically upgraded accordingly. Further detail is provided on this method of processing events in the detailed description below.

When a network event is queued to the VWN Processing Engine, it is queued with the required information to access the data stores, such as username, device type, location etc. This is performed in one of two ways. If the User/device is connected to a network operated by the invention, the invention can obtain these indices from it's own network modules and through communication with standard devices operating in the network such as DHCP servers. Where the User/device connects to the VWN across physical networks not operated by the invention (but where the invention provides the services), preferably a VWN client on the User's device supplies the information needed to index the data stores when processing a network event. This information can include, but is not limited to, username, device address, network addresses, local wireless media used, location information such as a GSM call number, and wireless WAN service being used.

The purpose of the VWN client is to ensure that the VWN Processing Engine has the information it needs to perform its functions. For example, when the invention processes an event, it accesses its databases to determine what to do for that particular User using that particular device at that particular location. However, in other circumstances the VWN will not know all these details. For example, if a User is connecting to the VWN from a remote site across a public network not operated by a VWN entity, the VWN knows the User that has connected, but not the device he/she is using or the local wireless technology they are using and the nature of the access service. Therefore the VWN client is needed to provide the details which the invention uses to index the databases

Where the VWN operates with VWN client software on User devices to pass the required information, the invention effectively operates a server-client model in this aspect. The invention has one or more servers operating in the VWN, and the VWN clients reside on the User devices, these clients communicating with the servers. The servers not only receive information from the VWN client for use in processing events, the servers can manage, update and modify the VWN client software. For example, if the policy entered for a User is changed, this information is updated the next time the VWN client connects causing it's operation to change. Alternatively, for devices which have a discover and connect capability, the client can be updated at any time.

The present invention implements a distributed wireless network operating system, and each instance of the system, when operating on a specific wireless network, can operate together in a hierarchical or peer-to-peer network configuration hence allowing the VWN to be scaled up to thousands of sites, and unlimited numbers of Users. The individual systems can be configured to tailor the VWN for optimum operation. The present invention delivers a uniform set of services optimised for Users, devices, and locations across a number of networks. The Users may actually be using many physical wireless networks (e.g. GPRS from Vodafone, a corporate wireless LAN, a Bluetooth public hotspot at a railway station) and the invention ensures they can receive services over all of these disparate networks.

The present invention offers a comprehensive set of rich services across a range of wireless networks to fully enable the benefits of wireless networking in a single solution. The present invention allows the organisation to customise the network through management and control interfaces, and an Application Programmers Interface.

The present invention addresses numerous problems. Below is a sample of such problems.

Content Tailoring: a User may have a number of different wireless devices such as a mobile phone, PDA, laptop, headset, web tablet etc. and the capabilities of these devices features are different. When delivering content or information to such a device, the invention uses policy information entered by a network administrator, to send the information over the optimum wireless medium, in the optimum format. For example, sending high graphics, high bandwidth content over a low bandwidth WAN connection is inefficient, and may be unsuccessful. Also, the content to be displayed may need to vary based on characteristics of the User such as access rights, causing the content to be tailored accordingly. Similarly a User may only be allowed access to certain services at certain locations; hence the invention tailors the content to the location of a User in the network.

Integrated Security: there are many different, device centric, technology specific, overlapping, inflexible and sometimes ineffectual security features available on wireless devices and wireless network access solutions today. This causes the problem of managing the security of wireless networks in an integrated manner, and requiring Users to remember different security passwords, invocation mechanisms dependent on the device they use, where they use it, and what service they use with the device. The invention allows a common, central security implementation which can be deployed throughout the network and applied to Users, groups of Users, location etc. For example, the administrator can enable a security feature across all Users, or just for one group of Users. Also, the administrator can allow the network security to be customised by an application, and can connect to other security servers (e.g. RADIUS) devices and databases.

Wireless Network Distribution System: the invention provides a common Distribution System which interfaces the physical networks to the invention, and when operating part or all of one or more of these physical networks can offer the same features across many different wireless access technologies such as Bluetooth and Wireless LAN. The Distribution System operates hand-off registration, roaming, QoS, broadcast & multicast features, privacy and load balancing at each Access Point in the wireless network. For example, connection to the network can be random and frequently leads to uneven connection leads, hence decreasing the efficiency of the wireless network. The invention controls the manner in which devices gain access to the network, by dynamically varying connection information, and hence balancing out the connection load.

Wireless Network Service Optimisation: the invention can be deployed at a number of sites to implement a large-scale virtual wireless network available at many locations. The network deployer could hold a database at each location, which allows fast connection times, and the invention provides automatic database synchronisation techniques to ensure data integrity throughout the virtual wireless network.

Messaging: a number of different messaging services are available today, such as SMS, instant messaging over the internet etc. The invention provides an integrated intelligent messaging service which can be applied to a number of media, based on a policy specified by the network administrator, such that the message is routed to the recipient over the optimum message system, tailored to the device and media, hence ensuring the most timely delivery, at the minimum cost.

Push Services: wireless devices are frequently put into low power or other dormant modes, where they cannot normally be communicated with. The invention provides a mechanism to wake-up these devices and allow information to be pushed to them asynchronously.

Discovery services: the whereabouts of a User, device, group of Users or group of devices may be unknown, hence this service is used to find the location across the entire VWN.

Positioning services: the invention can use information from the other services, such as the Discovery Service, to provide the absolute position of a User, or device. The invention is programmed with knowledge of the position of network infrastructure, and then maps information from one or more of these infrastructure devices to offer a real position of a device, which can then be used by another service, or an application. In this instance the invention connects this information directly to these other services, such as location dependent content delivery.

Tracking services: a wireless device may only be permitted to be in certain areas of the VWN at certain times, and this service is used to ensure validate these constraints, indicating where rules have been violated. This can entail complex schedule and algorithm checking.

Broadcast services: it is frequently necessary for services to operate on a number of devices. Users or locations, which may be situated on different or unknown networks, some of which may not intrinsically support broadcast services. The invention offers broadcast and multicast services to applications and other services.

OBEX services: OBEX is a transport layer protocol used by some low power wireless devices. There are two problems with such devices. The first is that OBEX devices frequently need to communicate with non-OBEX devices, and OBEX services normally communicate between two devices (e.g. PDAs) directly controlled by the devices Users, and are hence limited by the range of the wireless technology in the User devices. The invention provides two features; firstly a proxy to allow OBEX devices to communicate directly with IP based devices with User control, and secondly provides OBEX services across the VWN, not just directly between two devices at the same location.

Service Manager: many wireless network Access Point devices are standalone devices which need to be individually configured to provide the same access at each point in the VWN. The invention not only ensures that each Access Point can be configured for its permitted access mechanism from a central point, but that the same services can be made available at any Access Point regardless of their access technology, location and operational state. The VWN needs to offer the same services at any point in the network, but it may not be possible to implement the physical hardware or actual service module on each site, hence the invention can be configured to advertise services at each point, but re-direct the service request to a remote site(s). Additionally services can be configured to vary at different Access Points into the VWN, and for each device(s)/User(s) of the VWN

Hand-off: a number of wireless networks support hand-off capability to allow continuous service as a User moves around the wireless network location. However, hand-off should not be a standalone function, hence the invention links the hand-off process to other wireless network features such as security, access control, network capacity, voice services etc.

Capacity planning and installation: this service uses configured information and policy to direct other services in how the VWN should be installed and operated. For example the VWN may be required to provide voice services for one User at all locations throughout the VWN, and this service instructs others and monitors and analyses network operation to see if these policies are efficient for the VWN.

The invention effectively offers a Wireless Network Operating system that delivers a range of wireless network services to applications across a VWN. The Wireless Network Operating system has at its core the VWN Processing Engine which connects all the services together into an integrated solution, and provides an Application Programmers Interface (API) and other User interfaces for applications to use and customise these services, the control services for constructing and operating the VWN, and a common Distribution System for connecting all the wireless data paths together.

The invention uses a number of techniques to offer a set of services across a variety of different wireless networks and infrastructure. The invention includes a number of these specific services and features, and also how these differing services and features are integrated together in an innovative manner.

Wireless networks offer advantages over fixed or wired networks, and the invention fully enables these advantages in an optimal, easy to use, secure, robust, reliable manner. The underlying wireless network media, features, Users, devices, technologies and attributes are entirely handled by the present invention, presenting a simple interface to applications which can easily utilise the provided wireless services. This simple interface can also be used to customise the wireless network and the services it provides.

The invention can offer those services on a single wireless network composed of one or more wireless access technologies, or on many such networks distributed across multiple sites to form a single VWN which is controlled, managed and operated from a single (or multiple) locations, and by providing the same services across this VWN, offers seamless mobility to the User. The invention can operate the wireless network services on a number of different paradigms, or a combination of these paradigms; these include Users, devices, services and locations. Additionally these paradigms can be sub-divided into smaller logical (or physical) subsets, on which services can operate, and can be applied to form multiple separate VWNs over a shared infrastructure to ensure privacy.

### BRIEF DESCRIPTION OF THE DRAWINGS

Examples of the present invention will now be described in detail with reference to the accompanying drawings, in which:

FIG. 1 is a schematic representation of VWN system in accordance with the present invention;

FIGS. 2A to 2E show an example of data in each of a number of VWN data stores;

FIG. 3 illustrates a number of different interfaces and data formats that are compatible with one another using a VWN system according to the present invention; and,

FIG. 4 shows a VWN comprising a number of separate networks integrated using the present invention.

### DETAILED DESCRIPTION

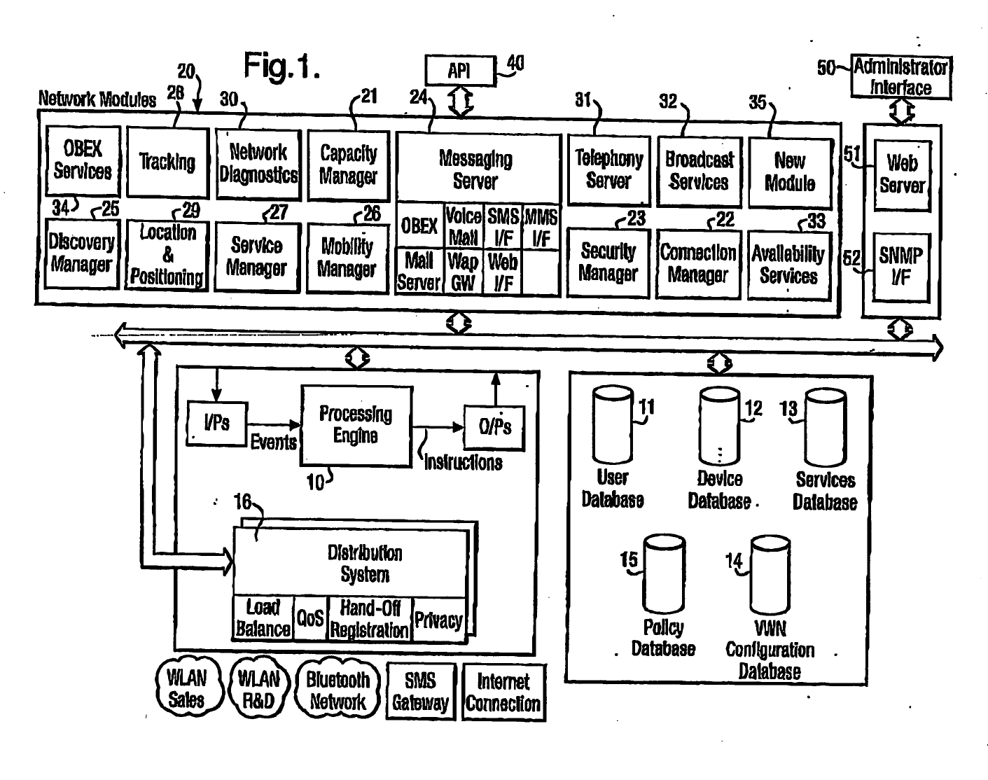

FIG. 1 shows an example of the basic architecture of a management system in accordance with the present invention. The VWN system includes a VWN Processing Engine 10 which has a number of interfaces to an external network or networks. The VWN Processing Engine is connected to a number of data stores. The data stores include a user database 11, a device database 12, a services database 13, a VWN configuration database 14 and a policy database 15.

The VWN system also contains a plurality of network modules 20, which can be grouped into three main categories; a control plane for forming and operating the wireless network, a set of features which enhance the wireless network, and a set of network services. Two important elements in the VWN system are a common Distribution System 16 capable of transporting data from multiple wireless access technologies over the network, and as mentioned above, the VWN Processing Engine 10 that is connected to each of the network modules as well as to the data stores and the Distribution System 16.

The network modules include a Capacity Manager 21, a Connection Manager 22, a Security Manager 23, a Messaging Server 24, a Discovery Manager 25, a Mobility Manager 26, and a Service Manager 27. There are also network modules that handle Tracking 28, Location and Positioning 29, Network Diagnostics 30, Telephony 31, Broadcast Services 32, Availability Services 33, and OBEX Services 34. There is also capacity for the addition of new modules 35. The functions of the various modules will be described in detail below. The Capacity Manager, for example, monitors the network capacity and the capacity of each network Access Point. If capacity is exceeded at a particular Access Point the Capacity Manager sends a signal to the VWN Processing Engine that to that effect.

The invention has a number of interfaces which can be used to configure, utilise, customise, monitor and optimise the services, features and control functions provided by the VWN. As will be described in detail below, an Applications Programmers Interface (API) 40 is provided which is for use by applications and furthermore, an Administrators interface 50 is provided. The Administrators Interface is comprised of two separate management interfaces, one a Simple Network Management Protocol (SNMP) interface 51 which can be operated by industry standard SNMP management applications such as HP Openview, and a second Web based User Interface 52 accessible through a standard Web browser. Note all these interfaces operate over IP protocols and are accessible through any wired port installed on the machine(s) running the invention, such as a LAN port.

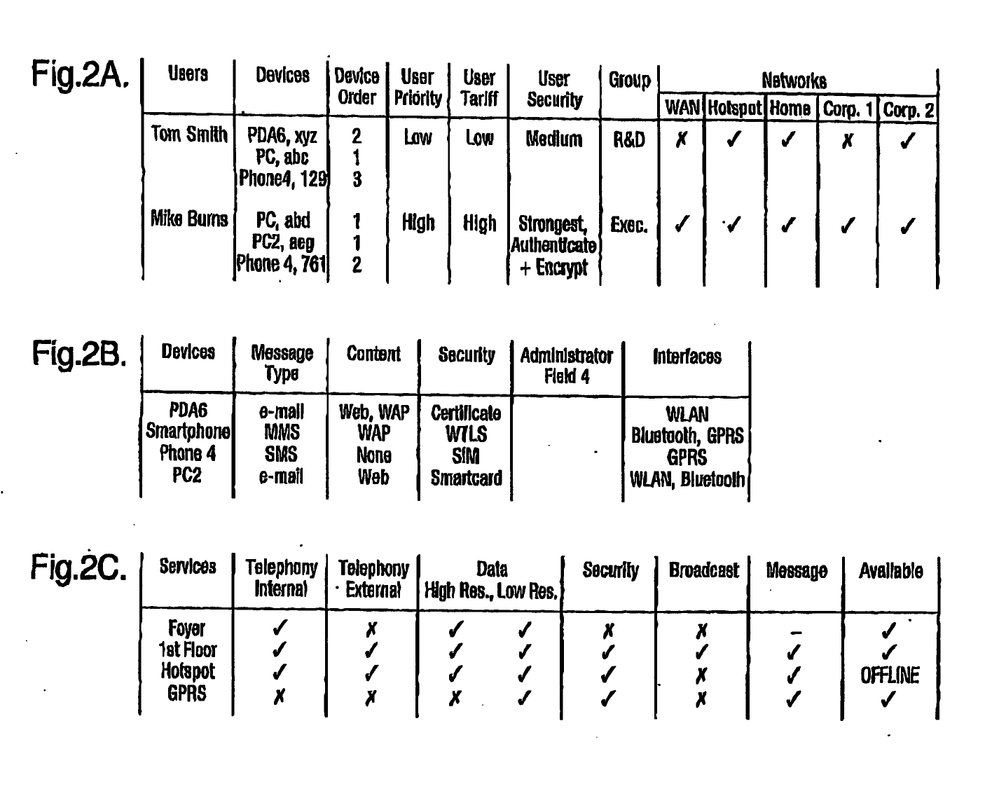

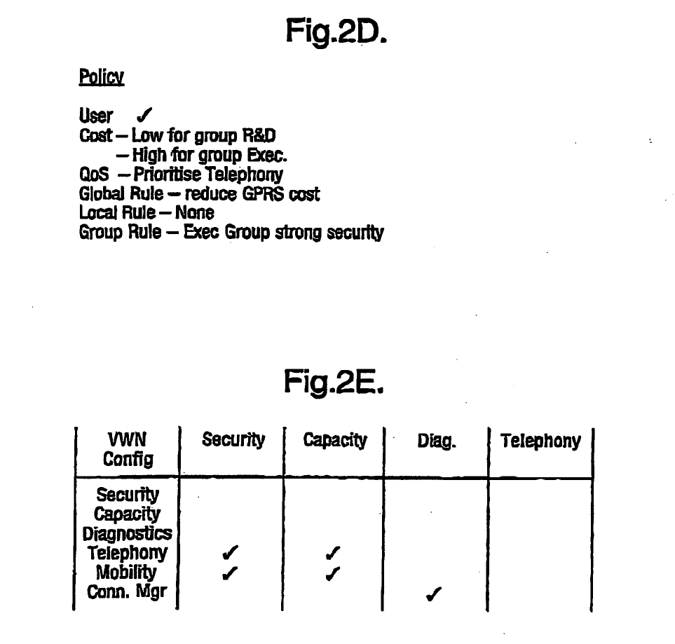

FIGS. 2A to 2E show simplified examples of the form of data in each of the data stores.

The user information in the user database is input by a network manager. FIG. 2A shows that for each network User there is listed the devices that the User has, the preferred device and format for messages, the level of services allowed to the User, the level of security features given to the User and costing information relating to the User. Further information may be included in the data store according to the requirements of the network.

Policy information is also input by a network manager and may be tailored according to the requirements of the organisation using the network. Policy information may relate to areas of the network, to particular Users or groups of Users. Examples of the types of policy that may be employed include only allowing low cost messaging to be used for a particular group of Users, only allowing limited network services at a particular location, always giving priority and a minimum quality of service to a particular User or only allowing a certain type of data, e.g. voice data, to be received and sent by a particular network Access Point.

The VWN configuration data is typically constructed during installation of the wireless network, but can be viewed and modified by a person experienced in the operation of the invention, details of new devices joining the network are then registered via the Distribution System as is explained below.

The service information may include the location of network infrastructure, the services offered by the network at each location and details about the requirements for particular events. For example, when a wireless end station is to be handed-off from one Access Point to another, a number of requirements for the new connection need to be taken into account in conjunction with the User information and the policy information. The new Access Point must be in range of the end point, have sufficient capacity, must be able to provide sufficient quality of service, must be able to offer a sufficient level of security for the new connection etc. The VWN configuration information therefore instructs the VWN Processing Engine to invoke the Mobility Manager, the Connection Manager, the Capacity Manager, the Security Manager and so on, to check that these criteria are met by a particular Access Point.

A simple example of the VWN in operation can be described with reference to a hand-off. A wireless end station moving away from the network Access Point to which it is connected will experience degradation in the connection. The end point or Access Point will then generate a request for hand-off to another Access Point. The VWN Processing Engine, upon receipt of the request will look up data relating to the User and device from the data store and will check the relevant policies. The Connection Manager will also ascertain the location of the device and Access Point and the available Access Points for a hand-off. Data relating to the available Access Points is retrieved by the various network modules as detailed by the configuration database and policies relating to the Access Points are checked. In this example, it is ascertained that there are five Access Points in a suitable location to receive the hand-off. However, it is a policy that one of these Access Points is reserved for voice data and is therefore not suitable. The Capacity Manager establishes that two of the remaining four Access Points have insufficient capacity. The Security Manager establishes that only one of the two remaining Access Points offers a sufficient level of security. There is therefore only one suitable Access Point and so the VWN Processing Engine and Distribution System instruct the Mobility Manager to affect the hand-off to that Access Point. In this manner a combination of set and User defined criteria are used to automatically manage the network for optimum operation.

Another example of the operation of the present invention is in the processing and delivery of messages. The VWN receives a request to deliver a message to User X. The message is received by the VWN as an email message, and the Messaging Server queues this request to the VWN Processing Engine. The VWN Processing Engine looks up User data relating to X, such as the devices he has and the types of data formats they can receive. Policies relating to X are also checked. The VWN Processing Engine instructs the Connection Manager to ascertain whether X is connected to the network, and if so where he is located, which may involve communication with a client on the device to determine the access network it is using. If X is not connected to the network the VWN Processing Engine will initiate a discovery for User X using the discovery service. From these enquiries it is established that User X has a mobile telephone supporting SMS messaging and a PDA supporting Bluetooth, both of which are currently connected to the network. There is also a policy for User X that the cost of any messages must be below a certain threshold. This policy makes the PDA the only suitable receiver for the message. The VWN Processing Engine then instructs the messaging engine to deliver the message to the PDA using Bluetooth. The message is therefore routed to the PDA via a Bluetooth gateway.

A more detailed example of this type is given later on but the basic operation of the invention can already be seen. The VWN Processing Engine modifies the general request to send a message to User X based on stored data, to produce a specific instruction to send the message to a particular device using a particular data format by routing it via an appropriate gateway. The invention thus allows different network technologies to be integrated in this manner.

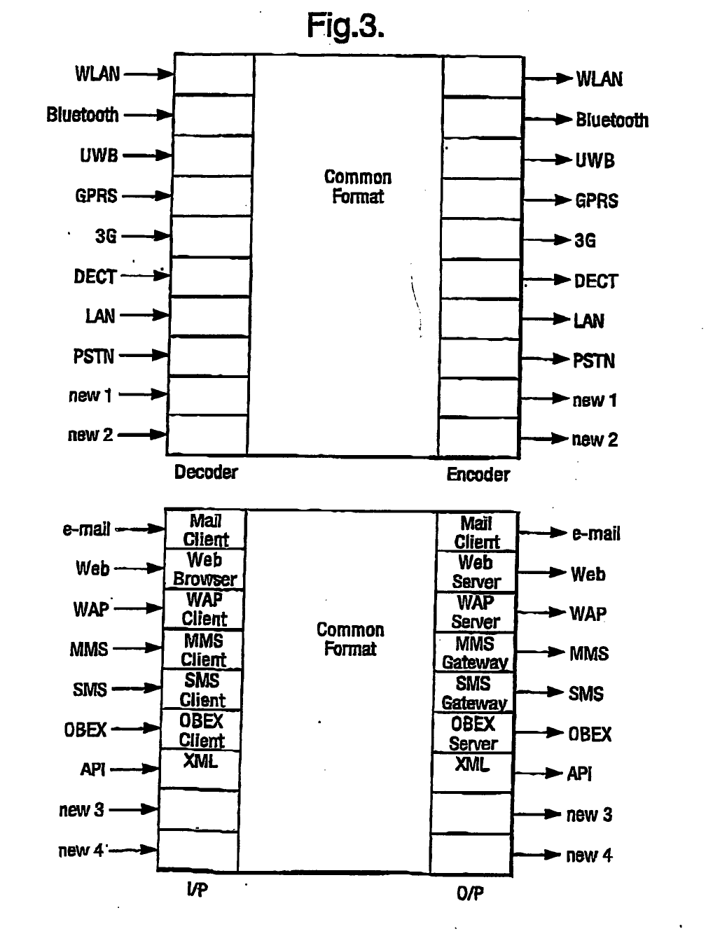

FIG. 3 illustrates schematically a few of the possible interfaces and data formats that can be integrated using the present invention. FIG. 8 is in no way exhaustive and new technologies and interfaces can be added when they arise.

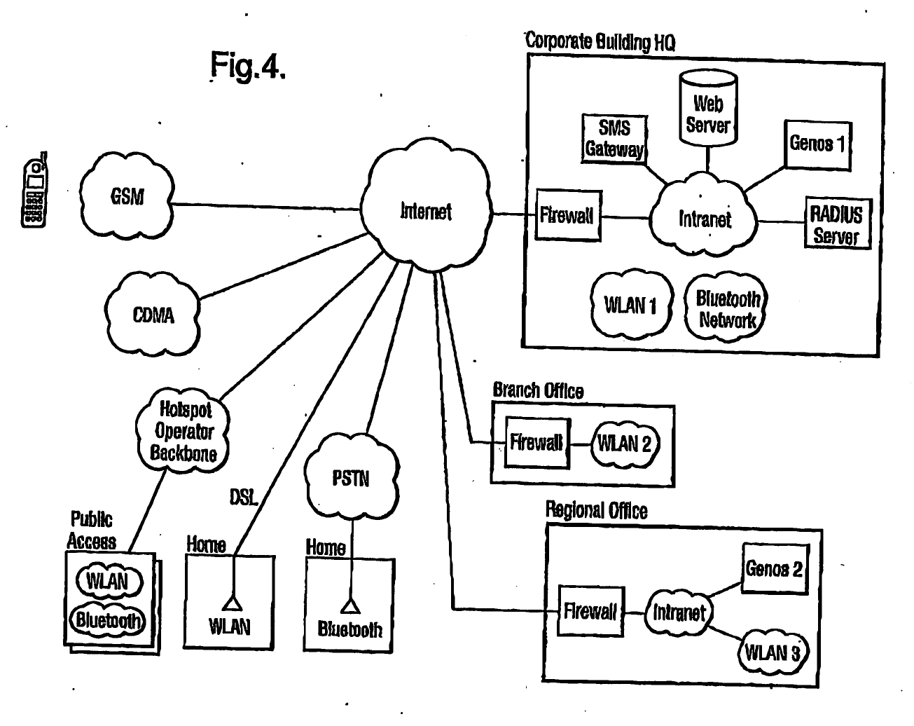

FIG. 4 shows Bluetooth, Wireless LAN (802.11b, 802.11g, 802.11a etc.), GPRS and 3G based access methods and networks which can all be combined to form a single VWN. The VWN of the present invention operates to allow this integration and offer services across the entire VWN. The management system for the VWN includes a number of databases, as described above, and each time a service is performed, these databases are accessed by the VWN Processing Engine to enact the services.

A number of services will now be described in accordance with an example of the present invention:

a) Security: the Security Service permeates the entire management system, and is not simply a standalone service. The Security Service offer 5 levels of security (device authorisation, link level, network layer, fire walling and application level) and the invention provides integrated control and management of these levels allowing complex management policies that can be implemented on devices, Users, services, locations, and groups and combinations of these. Taking each of these in turn, the Security Service can perform:

i) device level checking of addresses before allowing connection to the network, or locations within the network. Any incoming connection requests, or traffic on unauthorised connections are checked against the selected database information.

ii) link level authentication and encryption. When a device is connected the policy information is checked, and if authentification is required, the security service will challenge the User/device and perform authentication, and if successful, encryption over the air. The Security Service controls the link keys used in authentication and periodically expires these under administrator control. The Security Service also sets the period which devices can bond, or establish link keys.

iii) once link level communication is established, the Security Service enforces network level authentication which ranges from straightforward authentication using the local database with PAP or CHAP, or use of external RADIUS servers or external databases.

iv) the Security Service also provides firewalled access to the VWN. Once a network level connection is established, the Security Service only allows traffic to pass to/from specified IP addresses and subnets, and applies this on a par protocol basis (e.g. web traffic is allowed).

v) application level security such as VPNs, HTTPs etc. The security service is tailored to accommodate these techniques; e.g. selection of NAT aware protocols where possible.

The integration of all these security services is a result of the present invention. Different security interfaces are connected through what is effectively an authentication gateway (e.g. incoming link level requests should be re-routed to an external RADIUS server), and the present invention manages how they can be applied to services, Users, devices and locations throughout the VWN. As will be described below, an Application Programmers Interface (API) also allows these security services to be customised by an application; for example the VWN may require unknown devices and Users to connect to the VWN hence requiring device level checking, link level security and network level security to be disabled, or default to a limited access mode through the firewall on connection. A higher layer application can then establish a link key or network level password and User name, and then re-configure the database settings for that User/device, enabling specified secure services for future connections.

Note, other network modules and external elements such as subscription servers can request and utilise features of the Security Service, such as re-authentication or expiry of security credentials. Additionally the invention allows external security services to be requested by other network modules and applications, such as specification of an external RADIUS server address in a security request. For example, if a message needs to be delivered to a user across a public network which is insecure, the VWN Processing Engine will invoke the Security Manager to apply the required security service, such as authentication, authorisation and encryption.

b) Content tailoring: this service allows the VWN to tailor content for a location, a device, a service or a media. Consider the User connects to an intranet service in a hotel, and the service offers information which is specific to each location. When the User connects to a network Access Point, the service re-directs incoming Web requests to a Web page linked to that Access Point by intercepting the HTTP stream.

When information needs to be routed to a User who has multiple wireless devices, the VWN Processing Engine will use the policy for that User to select the optimum delivery media; this could be the most cost effective, or the quickest etc. When the VWN Processing Engine selects the media, the content tailoring service also takes dynamic information from the VWN to influence the VWN Processing Engine in selecting the appropriate media (e.g. the SMS service is currently proving unreliable).

When a device connects to the VWN and starts to use a particular applications (e.g. an information update service), the content tailoring service will tailor that content for the device; the VWN Processing Engine will access the policy and information for that device, and this may indicate the device is a WAP end-point, hence the content manager will direct the source through an HTML→WML converter and through a WAP gateway. Alternatively, the content manager can connect the IP session directly to a WAP source rather than an HTML source by re-programming the IP traffic-forwarding engine for that IP session.

c) OBEX Services: two services are offered for OBEX devices, a proxy and a gateway. Traditionally when two Users wish to exchange objects, they manually cause the devices to discover each other, and then request an object exchange (or rather object push or pull). This causes the OBEX protocol to be invoked, one device becomes an OBEX server, the other OBEX client and the two devices exchange data such as files, synchronisation information, business cards etc. This is limited to the range of the two devices; hence the VWN OBEX service can extend this service to operate over the entire VWN through proxies. For example, if two Users are conversing over a voice call, and want to exchange OBEX information across the VWN, the sender will request an OBEX Service from the VWN which will advertise an OBEX User as >Local OBEX proxy=; the User will then operate the object push which is sent by the OBEX service to the messaging engine, which decodes the object information and the User details, maps this to a connected Username, and causes the object to be pushed to the intended receiver. The User device may alternatively operate a VWN client which can indicate directly to the VWN server the destination party which is used by the OBEX proxy. The same process can be performed in reverse.

When offering the OBEX gateway service, the administrator configures a mapping between a Bluetooth device address and an IP address. When the User wishes to push or pull an object to/from the mapped destinations, the VWN Processing Engine advertises an OBEX gateway service, which participates in an OBEX exchange, then converts the object from an OBEX payload to an IP payload, forms a connection to the mapped device, and transmits the payload.

d) Push and Wake-up Services: this service is used in conjunction with other services when passing messages, pushing content, routing voice calls etc. An application such as a WAP Push Server will decide it wishes to push information or content to a User(s); the invention offers a WAP Push Access Protocol client which receives messages from the Push server indicating the destination addresses and the content. The Push Service passes the request to the VWN Processing Engine which causes the corresponding device address to be looked up and returned to the Push Service, which then queries the Connection Manger to see if a valid connection is active for that device. If yes, then the Push Service forwards the information to the Access Point returned by the Connection Manager, and the Access Point destinates the information. However, if there is no active connection, the Push Service will request a Device Discovery, which will locate the device. The Push Service will then forward a ‘wake-up message’ to the device which alerts the User to a queued message in the Push Service. If the User responds to the alert message by enabling the relevant WAP application, the original Push content is then routed over the VWN.

e) Location Services: these straightforward services allow other services, Users and applications to determine the whereabouts of a device or User on the VWN. The Location Services include discovery, positioning, availability and tracking. An example of how they are used to is when an application sends a “Locate User X” message to the VWN across the API: The Discovery Service is then passed this request through an internal interface, and then queries the User information database to find out details on the User. The Connection Manager is then queried to see if any of the returned devices are active, and if so, the returned Access Point is passed to the application across the API. If no device is active, the Discovery Service will then request an enquiry for the device at each point in the VWN, or a part of the VWN. Additionally, when a device or User connects to the VWN, other users can be the Availability Services to learn of the whereabouts of that user or device. The User wishing to learn the whereabouts of another User simply connects to the invention through one of it's management interfaces (e.g. Web interface) and requests details on the required User.

f) API: the Application Programmers Interface allows applications to make direct use of the services offered across the VWN and modify the database content and policy if necessary. The API is a networked API, with messages defined as XML schema passed in HTTP payloads over TCP/IP connections. Three types of operation are provided over this API; firstly request information such as a connection status on a specified Access Point, secondly set information/configuration such as a security setting, and finally perform actions on the VWN such as >Perform Network Inquiry on this group of Access Points. The requested information can be programmed to be passed to an application asynchronously (e.g. when a device connects to the network). Finally, the API can offer privacy when the VWN is providing services for a number of different organisations across a common infrastructure.

Once the VWN Processing Engine and associated network modules have performed a service or feature, information may be required to be passed to a wireless device, across one or more wireless networks. The VWN system includes a Distribution System which interfaces all the physical wireless networks to the VWN and connects the data paths together across a common data path. Specific examples are given below.

a) Broadcast/multicast: each wireless access technology has a different broadcast methodology. When a service such as the Push Service, requires information to be passed to a number of devices or Users, the VWN Processing Engine passes the information content, media and addressing information, and access rights to the Distribution System. The Distribution System then routes the information content (e.g. mail message, voice packets etc.) to the specified Users/devices through specific knowledge of each wireless networks broadcast capabilities, and the User/device access rights at each location in the VWN. For Bluetooth, there will be some parts of the network which support Personal Area network Profile, which supports broadcasts, hence the Distribution System will forward the message to each Bluetooth Access Point in the Bluetooth Wireless Network, which will forward it onto the air broadcast medium; for arts of the Bluetooth network that only support point-to-point based LAN Access Profile, the Distribution System instructs each Access Point authorised for use by that device/User to send the information to each listed device on its point to point connection. Where the local air network is connected to some Users who should receive the broadcast, and some who should not, the Distribution System uses multicast addressing.

b) Hand-off: each wireless access technology has its own mechanism for performing hand-offs. The Distribution System implements a common mechanism for implementing hand-off with all hand-offs being controlled and implemented under control of the same policy, security, capacity and QoS services, hence allowing a single high speed, managed, controlled infrastructure rather than separate infrastructures for each technology requiring complicated interfacing to the common services. For example, the Distribution System operates a single hand-off controller which interfaces to the security component of the Connection Manager which authorises if a device/User can be handed off to/from an Access Point, and if any security checks need to be performed, such as authentication or key re-generation. Additionally the Distribution System operates a single registration server which is used in network formation, which allows each Access Point to be programmed to locate the same registration server through a single DNS entry offering simple management and control. When a new wireless Access Point joins the VWN, it contacts the local Distribution System server which registers it, and provides information to the Access Point on back-up registration servers. The Distribution System also operates a single inter Access Point Protocol which passes hand-off messages between Access Points to synchronise connection transfers, reducing the network processing overhead.

c) Resilience: The Distribution System is resilient as it can operate on a number of different machines in parallel. The multiple Distribution Systems providing resilience form a domain, and communicate with each other periodically through a simple protocol in order to determine they are still available. If/when a Distribution System fails, the protocol alerts the other Distribution System(s) to this fact, and the back-up Distribution System cut in, and then immediately off the same services at that point in the VWN. It is this transfer of service availability that is offered by the invention, which is accomplished by offering the same Bluetooth SDP records, or WLAN location, User or device access rights.

d). Load balancing: the Distribution System also provides optimum dynamic utilisation of the attached wireless air channels by monitoring the capacity at each Access Point, and subsequently modifying the connection process. If a particular Access area is above a capacity passed to the Distribution System by the Capacity Service (e.g. only 1 voice call per Access Point, only 4 Users per Access Point etc.), the Distribution System will cause the Access Point not to respond to inquiries at that time. The Distribution System also returns network utilisation information to the VWN Processing Engine for dissemination to various modules; e.g. if the WLAN network is running at close to capacity, it will be passed to the Messaging and Content Tailoring Services which will use this when selecting which media and/or content type to use.

e) Qos: the Distribution System also works in conjunction with the Connection Manager, the Network Policy and the Capacity Planner to provide Qos, and feedback to other services. The Network Policy is set-up to provide Qos for a User (e.g. always guarantee this User or group of Users priority over others, always offer this User priority in a group of locations), or for applications and services crossing the VWN. For example, when a User connects to the VWN, if that User has priority, further services will not be provided on that Access Point if they violate the Qos requirements of the connected User. If a hand-off is required, then existing connections may be moved to adjacent Access Points to maintain Qos.

f) Privacy: The invention can operate a number of simultaneous, but isolated VWNs over a common infrastructure. To ensure that the data for each network is kept private, the Distribution System can break down the data path into separate data paths through the use of Virtual LANs.

The VWN may include a number of VWN Processing Engines at different locations. An organisation may prioritise security and ease of management to be their primary concern, hence all VWN Processing Engines in a VWN will be configured to use a single remote database (or a list of databases with preferences) which requires each VWN Processing Engine in the VWN to contact these databases each time a service is used. Alternatively, the organisation may wish speed of connection to a service be paramount, hence requiring local services to use the local databases; however this requires databases to be kept up to date, and Internal Control Services then communicate to keep these databases updated. This communication involves update of device information, security rights, payment details etc, and is performed across the API of each VWN Processing Engine, or through the management interfaces; each time a record changes, this information is distributed across the entire VWN. External databases can also be incorporated into the VWN, with synchronisation performed with use of the API and standard database access methods such as LDAP, ODBC etc.

The services offered across a VWN can be implemented by a single instantiation of the service and its accompanying physical interfaces at a single site, or implemented at every site. For example, an organisation deploying a VWN may have an SMS gateway at only a single location, but can offer this service from any point in the VWN. Therefore, each local VWN Processing Engine is configured to advertise the SMS service (either through low level control of Bluetooth SDP records, or high means of advertising on a Web page), and when a message is received on a local VWN Processing Engine to use this service, the task is passed to the central VWN Processing Engine providing the service. This is done through definition of internal control messages, defined file and task formats etc, which are transmitted over the channels established by the communications agents; these are typically secure authenticated tunnels such as IPSec based VPNs.

The VWN Processing Engine operates on a standard OS (e.g. LINUX, WindowsNT) and inter-connects all the services operating on a VWN. The VWN operator/administrator, through setting various policies and User/device information in the databases, sets up how various service will operate.

For example, when a messaging service is set-up for a User X (see section on messaging below), the network administrator will enter the devices a User has, any content specific information such WAP vs. Web browser, the network inbound message interfaces (e.g. mail client), the preferred outbound messaging interfaces for each application, and their precedence. When a User wishes to get a message to User X, the User sends a message to one of the inbound messaging ports (e.g. send a mail to the mail address of the invention, such as UserX@MyCorporation.WirelessMessagingService), which is received by the mail client which forwards the message to the VWN Processing Engine indicating message type and other details such as broadcast/multicast, which is responsible for causing the message to be delivered. The process is described below.

The VWN Processing Engine first checks its configuration information to establish if a local messaging service is available, and if not, forwards the message to a pre-programmed remote VWN Processing Engine which will cause delivery of the message. If a local messaging service is available in this installation of the system, the VWN Processing Engine checks to see if information is stored locally for that User, device and service; if yes the information is retrieved, if not a remote database is contacted for the information (see above). The information may contain at least the following:

User has SMS phone, Wireless LAN PC, Bluetooth enabled PDA (with LAN Access Profile, Object Push Profile, and device discoverable support);

addresses for devices are phone number +44 1753 000200, PC WLAN MAC address is 0000F6 123456, PDA Bluetooth device address is 0000F6 654321;

the User is authorised to use the group of networks >ALL AIRPORT LOUNGES= throughout the VWN;

use local authentication and authorisation servers for this User, use Bluetooth Security;

the last point of Access to the VWN was this local installation at 9:46:21 today;

the local management installation has a Bluetooth wireless network;

the User is authorised to use centralised SMS services available on sub-network 4 of the VWN;

the Bluetooth network support mail services across LAN Access profile and Personal Are networking Profile;

video messages should be routed only to the PC, e-mail messages may be destined to the PC or the PDA in that order; text messages may go to the phone, the PDA and the PC in that order;

if the PDA is not connected, a connection can be established to it;

searches may only happen on the “Public Access” group of Access Points in the local network;

multicast services are available on the network.

The VWN Processing Engine processes the message type “Email”, and the information from the database(s) which indicates that the message can only go the Users PDA over the Bluetooth network using Object Push Profile; therefore the VWN Processing Engine requests from the Connection Manager if that Bluetooth device is connected. The Connection Manager reply indicates no connection is active, hence the VWN Processing Engine requests the Discovery Service to look for Bluetooth device 0000F6 654321 on the Group of Access Points called “Public Access”. The Discovery Service (described below) returns a positive result indicating the device can be found within range of two Access Points; the VWN Processing Engine then requests the Connection Manager to open a secure connection to that device through one Access Point, and requests an Object Push Service to the device, which is successful. The VWN Processing Engine then instructs the Messaging Engine to translate the e-mail to an OBEX Vmessage format suitable for use over the Object Push Service; on completion of this task by the messaging engine, the VWN Processing Engine then passes the message, with the device address, and connected Access Point address, to the Distribution System which routes the message.

The configuration and policy set by the network administrator clearly can cause the VWN Processing Engine to co-ordinate and perform more and different tasks. For example, a message may be destined for multiple recipients, hence the broadcast service is used, an external authentication server is configured, hence the VWN Processing Engine will invoke the authentication etc. The VWN Processing Engine communicates with other services through the API (which is a network wide XML based interface), and other internal mechanisms, which include proprietary message interfaces and standardised interfaces such as LDAP, RADIUS, OS sockets etc.; internal header definitions, internal message definitions facilitate these communications. A detailed example of the use of these internal mechanisms is given below.

Consider a variant of the hand-off example introduced earlier where a connected device moves away from an Access Point hence causing the Access Point to send a message to the Mobility Manager in the invention. The Mobility Manager receives the message then queues an Event Message to the VWN Processing Engine, where this message includes general information such as the device MAC address, the network address being used by the device, the user name, the location of the Access Point, and information specific to the event including an event number, event type, a Network Neighbour List (NNL) indicating adjacent Access points it has deemed capable of accepting the hand-off of this device, the service in use (e.g. telephony) and the current security level in operation (authentication & authorisation & encryption).

The VWN Processing Engine reads the Event Message and decodes the event type as a hand-off event, and calls the set of routines required to affect this event. The routine instructs the VWN Processing Engine to access the inventions stores, which return information in defined Database Messages; the messages indicate that the network is set to operate security, operate Capacity Management (from the VWN Configuration Database), that the user must operate security (from the user database), the device is a Bluetooth PDA capable of authentication, encryption, and that the Access Points at this location are capable of offering Telephony Services and Security.

The VWN Processing Engine uses the NNL to create a Command Message which is sent to the Capacity Manager requesting it to validate if the Access Points in the NNL are capable of accepting the hand-off. The Capacity Manager performs this function and in response generates an Event Message to the VWN Processing Engine indicating the result of the command, which in this case indicates two Access Points (AP18 & AP19) are capable of accepting the hand-off.

The VWN Processing Engine reads this Event Message then builds a command instructing the Mobility Manager to affect the hand-off to one of the Access Points using the defined Command Messages, but not to enable communication once the hand-off is complete. The Mobility Manager decodes the Command Message, performs the command then queues a response to the VWN Processing Engine in the form of an Event Message including which AP was used for the hand-off.

The VWN Processing Engine reads response from the Mobility Manger, each Message including the Event Number & Type, which is decoded. The VWN Processing Engine routine then builds & delivers a Command Message to instruct the Security Manager to authenticate the device then establish encryption, and if successful enable the connection for data transfer. The VWN Processing Engine also issues a Command Message to the Capacity Manager indicating which AP has picked up the connection, allowing the Capacity manager to update it's status.

The Security manager affects the command from the VWN Processing Engine, and when successful returns the result again in the form of a defined Event Message queued to the VWN Processing Engine.

Finally, for this event, the VWN Processing Engine reads the Event Message from the Security Manager, whereupon the VWN Processing Engine routine causes it to issue a Command Message to the Mobility Manager indicating the event is complete, then update it's own log file and statistics.

Note, under certain circumstances the VWN Processing Engine will command the modules to communicate directly to process an event, hence increasing the throughput of the invention. The same Event, Database and Command Messages are used, and this effectively provides an element of distributed processing in the invention as information on the routines are disseminated to the modules. The manner of exchanging these messages, in either centralised or distributed modes, is through the use of standard mechanisms such as sockets, TCP connections, mailboxes etc.

1. A virtual wireless network (VWN) system comprising:
a number of networks;
a user data store including information relating to network Users;
a device data store including information relating to network devices;
a services data store including information relating to types of service available at network locations;
a policy data store including information relating to network policy to be implemented on the VWN;
a VWN configuration data store including information on the operation of the VWN;
a plurality of network modules; and,
a VWN Processing Engine connected to each data store and to each network module, and having an input for receiving network events, a set of routines for processing each event, and an output for commanding network modules in use, the VWN Processing Engine controlling the operation of one or more network modules in accordance with a network event and in dependence on information in each of the data stores.

2. A system according to claim 1, further comprising a Distribution System connected to the VWN Processing Engine, the combination being operative to deliver services across the VWN.

3. A system according to claim 1 further comprising an Application Programmers Interface (API) for providing an interface to the VWN to allow applications to one or more of configure, utilise, customise, monitor and optimise services across the VWN.

4. A system according to claim 3, in which the API is networked.

5. A system according to claim 1 in which the VWN Processing Engine is adapted to operate in a client-server mode with a VWN client on a user's device, when the details of the device are not registered with the VWN through the normal operation of the VWN.

6. A system according to claim 1, including a plurality of data stores located at different locations within the VWN.

7. A system according to claim 1, comprising a number of VWN Processing Engines positioned at different locations within the VWN.

8. A system according to claim 1, in which a network event is one or more of a group consisting of defined Event Messages which include information required by the VWN to process the network event.

9. A system according to claim 1, in which the VWN Processing Engine effects a set of routines in response to network events, these set of routines being adapted by the information contained in the stores which are relevant to an event, wherein the adapted routine causes the network modules to execute a related series of operations optimised according to the requirements of one or more of the data stores.

10. A system according to claim 1, in which a network module comprises a set of functions that can be caused to be executed by the VWN Processing Engine, where the network module can generate events and communicate results to the VWN Processing Engine through Event Messages and can accept commands from the VWN Processing Engine through Command Messages.

11. A system according to claim 1, where the network modules may be commanded by the VWN Processing Engine to communicate directly with each other and the data stores in order to affect a specified event.

12. A system according to claim 1, including network modules using a plurality of different communications standards.

13. A system according to claim 1, comprising a plurality of separate networks implemented over one or more communications standards at one or more locations.

14. A computer program product comprising computer executable code for establishing and operating a virtual wireless network (VWN) system according to claim 1.

15. A method of establishing a virtual wireless network (VWN) across one or more networks, comprising the steps of:
providing a user data store including information relating to network Users;
providing a device data store including information relating to network devices;
providing a services data store including information relating to types of service available at network locations;
providing a policy data store including information relating to network policy to be implemented on the VWN;
providing a VWN configuration data store including information on the operation of the VWN;
providing a plurality of network modules; and,
providing a VWN Processing Engine connected to each data store and to each network module, and having an input for receiving network events, a set of routines for processing each event, and an output for commanding network modules. In use, the VWN Processing Engine controlling the operation of one or more network modules in accordance with a network event and in dependence on information in each of the data stores.

16. A method according to claim 15, wherein the policy data store instructs the VWN to operate services across the VWN which conform to the requirements of a deployer.

17. A method according to claim 15 wherein the VWN provides a common set of services across multiple different physical networks.

18. A method according to claims 15 further comprising a Distribution System connected to the VWN Processing Engine, the combination being operative to deliver services across the VWN.

19. A system according to claim 18, wherein the Distribution System provides a common set of Features and Control for multiple physical networks which form part or all of the VWN, hence providing an integration of these disparate networks and a uniform platform for provision of services across these physical networks.

20. A method according to claims 15 further comprising providing an Application Programmers Interface (API) for providing an interface to the VWN to allow applications to one or more of configure, utilise, customise, monitor and optimise services across the VWN.

21. A method according to claim 20, in which the API is networked.

22. A method according to claims 15 in which the VWN Processing Engine operates in a client-server mode with a VWN client on a user's device when the details of the device are not registered with the VWN through the normal operation of the VWN.

23. A method according to claims 15 comprising providing a number of VWN Processing Engines located at different positions in the VWN.

24. A method according to claim 15, in which a network event is an Event Message which includes information required by the VWN to process the event.

25. A method according to claims 15 in which the VWN Processing Engine affects a set of routines in response to events, these set of routines being adapted by the information contained in the data stores which are relevant to this event, wherein an adopted routine causes the network modules to execute a related series of operations optimised according to requirements of one or more of the data stores.

26. A method according to claim 15, in which a network module comprises a set of functions that can be caused to be executed by the VWN Processing Engine, where the network module can generate network events and communicate results to the VWN Processing Engine through Event Messages and can accept commands from the VWN Processing Engine through Command Messages.

27. A method according to claim 15, wherein the network modules may be commanded by the VWN Processing Engine to communicate directly with each other and the data stores in order to affect a specified event.

28. A method according to claims 15 implemented with network modules using a plurality of different communications standards.

29. A method according to claims 15 implemented over a plurality of separate networks established using one or more communications standards at one or more locations.
